(19) United States
(12) Patent Application Publication
(10) Pub. No.: US 2007/0158812 A1
(43) Pub. Date: Jul. 12, 2007

(54) Method of testing wires and apparatus for doing the same

(75) Inventor: Megumu Sagiyama, Izumi-Shi (JP)

Correspondence Address: YOUNG & THOMPSON, 745 SOUTH 23RD STREET, 2ND FLOOR, ARLINGTON, VA, 22202, US

(73) Assignee: NEC LCD TECHNOLOGIES, LTD., KAWASAKI-SHI (JP)

(21) Appl. No.: 11/649,832

(22) Filed: Jan. 5, 2007

(30) Foreign Application Priority Data
Jan. 6, 2006 (JP) 2006-001439

(51) Int. Cl. H01L 23/02

(52) U.S. Cl. 257/686

(57) ABSTRACT

In a substrate including a plurality of first wires to be tested, and a plurality of second wires each defining a capacity with each of the first wires, a method of testing whether said first wires are defective or not, includes (a) applying a voltage to the first wires, and (b) detecting a capacity defined between the first and second wires while the step (a) is being carried out.

### BACKGROUND OF THE INVENTION

1. Field of the Invention

The invention relates to a method of testing whether wires are defective or not, and an apparatus for doing the same.

2. Description of the Related Art

A TFT substrate 1000 is tested with respect to point defect and line defect thereof as follows.

As illustrated in FIG. 1, each of drain terminals 1001A to which each of drain wires 1001 formed on the TFT substrate 1000 is electrically connected is caused to make contact with a detection probe 1003, and each of gate terminals 1002A to which each of gate wires 1002 formed on the TFT substrate 1000 is electrically connected is caused to make contact with a detection probe 1004. Thus, the TFT substrate 1000 is electrically connected to a tester (not illustrated) including a capacity-detector and a controller, through the detection probes 1003 and 1004.

The tester applies a predetermined voltage to the TFT substrate 1000 to thereby write electric charges into and read electric charges from capacities of pixels 1007 formed on the TFT substrate 1000. By doing so, the tester detects point and line defects existing in the TFT substrate 1000.

A process of detecting defects in the above-mentioned manner is called a pixel capacity detection process.

As illustrated in FIG. 2, a TFT substrate 2000 in which pixels and transistors are not yet fabricated (for instance, gate wires are already formed thereon) is tested as to whether gate wires 1002 and COM wires 1005 are short-circuited to each other, by applying a predetermined voltage to gate terminals 1002A, and detecting a current running from COM terminals 1005A through a current detector (not illustrated).

As illustrated in FIG. 2, the COM wires 1005 are electrically connected to the COM terminals 1005A, which are electrically connected to a current-detector (not illustrated). Each of the gate wires 1002 is electrically connected to the gate terminal 1002A which is electrically connected to a controller (not illustrated) through a detection probe 1004.

A current does not run into the current detector through the gate wire 1002 not short-circuited with the COM wire 1005. In contrast, a current runs into the current detector through the gate wire 1002 short-circuited with the COM wire 1005. Hence, it is possible to detect that one of the gate wires 1002 is short-circuited with the COM wire 1005.

However, a test to be carried out in accordance with the conventional pixel capacity detection process is accompanied with a problem that since point and line defects are detected by detecting a capacity formed at the pixel 1007 formed on the TFT substrate 1000, it is not possible to detect breakage of the gate wire 1002 before the pixels 1007 are not formed.

In view of the problem, for instance, Japanese Patent Application Publication No. 2002-40075 has suggested a tester including a substrate for testing a gate line and a substrate for testing a data line both of which are comprised of a transistor and a capacity mounted on a probe unit. The suggested tester makes it possible to detect line defect of an active matrix substrate even before a pixel is formed.

However, the suggested tester is accompanied with a problem that the above-mentioned substrates for testing a gate line and for testing a data line have to be used, resulting in failure in simplification of the tester.

### SUMMARY OF THE INVENTION

In view of the above-mentioned problems in the prior art, it is an object of the present invention to provide a method of testing whether wires are defective or not and an apparatus for doing the same both of which make it possible to detect defectiveness in wires formed on a substrate more easily than the prior art.

In one aspect of the present invention, there is provided, in a substrate including a plurality of first wires to be tested, and a plurality of second wires each defining a capacity with each of the first wires, a method of testing whether the first wires are defective or not, including (a) applying a voltage to the first wires, and (b) detecting a capacity defined between the first and second wires while the step (a) is being carried out.

It is preferable that the step (b) is carried out by means of a capacity-detector electrically connected to the second wires.

It is preferable that the step (b) is carried out with a capacitance being electrically connected between the second wires and the capacity-detector.

It is preferable that the first and second wires extend almost in parallel with each other.

It is preferable that the first and second wires are formed in a common layer.

It is preferable that the second wires are collected into one terminal.

There is further provided, in a substrate including a plurality of first wires to be tested, and a plurality of second wires each defining a capacity with each of the first wires, a method of testing whether the first wires are defective or not, including (a) applying a voltage to the second wires, and (b) detecting a capacity defined between the first and second wires while the step (a) is being carried out.

It is preferable that the step (b) is carried out by means of a capacity-detector electrically connected to the first wires.

It is preferable that the step (b) is carried out with a capacitance being electrically connected between the first wires and the capacity-detector.

In another aspect of the present invention, there is provided an apparatus for testing whether first wires are defective or not in a substrate including a plurality of the first wires to be tested, and a plurality of second wires each defining a capacity with each of the first wires, including (a) a voltage-applier for applying a voltage to the first wires, and (b) a capacity-detector for detecting a capacity defined between the first and second wires.

It is preferable that the capacity-detector is electrically connected to the second wires.

The apparatus may further include a capacitance electrically connected between the second wires and the capacity-detector.

The apparatus may further include a capacitance to be electrically connected between the second wires and the capacity-detector, and a switch defining one of a first condition in which the second wires are electrically connected to the capacity-detector through the capacitance and a second condition in which the second wires are electrically connected to the capacity-detector without through the capacitance.

It is preferable that the first and second wires extend almost in parallel with each other.

It is preferable that the first and second wires are formed in a common layer.

It is preferable that the second wires are collected into one terminal.

There is further provided an apparatus for testing whether first wires are defective or not in a substrate including a plurality of the first wires to be tested, and a plurality of second wires each defining a capacity with each of the first wires, including (a) a voltage-applier for applying a voltage to the second wires, and (b) a capacity-detector for detecting a capacity defined between the first and second wires.

It is preferable that the capacity-detector is electrically connected to the first wires.

The apparatus may further include a capacitance electrically connected between the first wires and the capacity-detector.

The apparatus may further include a capacitance to be electrically connected between the first wires and the capacity-detector, and a switch defining one of a first condition in which the first wires are electrically connected to the capacity-detector through the capacitance and a second condition in which the first wires are electrically connected to the capacity-detector without through the capacitance.

In still another aspect of the present invention, there is provided a program for causing a computer to carry out a method of, in a substrate including a plurality of first wires to be tested, and a plurality of second wires each defining a capacity with each of the first wires, testing whether the first wires are defective or not, steps executed by the computer in accordance with the program including (a) applying a voltage to one of the first wires and the second wires, and (b) detecting a capacity defined between the first and second wires while the step (a) is being carried out.

The advantages obtained by the aforementioned present invention will be described hereinbelow.

In accordance with the present invention, while a voltage is applied to the first wires or the second wires, a capacity defined between the first wires and the second wires is detected by the capacity-detector. Accordingly, it is possible to simply detect a wire breakage in a gate wire formed on a TFT substrate even before a pixel and/or a transistor are fabricated on the TFT substrate, for instance.

Furthermore, in accordance with the present invention, a capacity defined between the first wires and the second wires is detected by the capacity-detector with a capacitance being electrically connected between the first or second wires and the capacity-detector. Thus, even if the first wires are short-circuited with each other, and further wire breakage occurs in the first wires, it is possible to simply detect both wire breakage and short-circuit in the first wires.

The above and other objects and advantageous features of the present invention will be made apparent from the following description made with reference to the accompanying drawings, in which like reference characters designate the same or similar parts throughout the drawings.

### BRIEF DESCRIPTION OF THE DRAWINGS

FIG. 1 is a plan view of a TFT substrate to be tested in accordance with a conventional process for testing whether wire breakage exists.

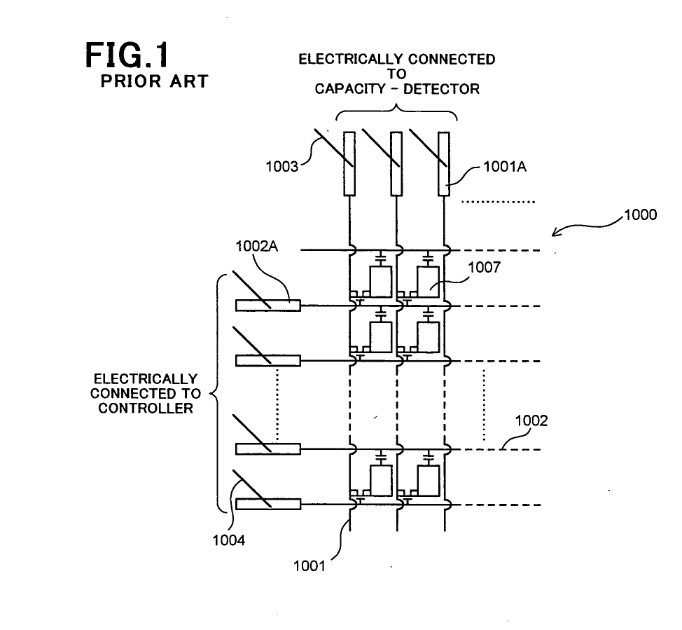

FIG. 2 is a plan view of a TFT substrate to be tested in accordance with a conventional process for testing whether wires are short-circuited to each other.

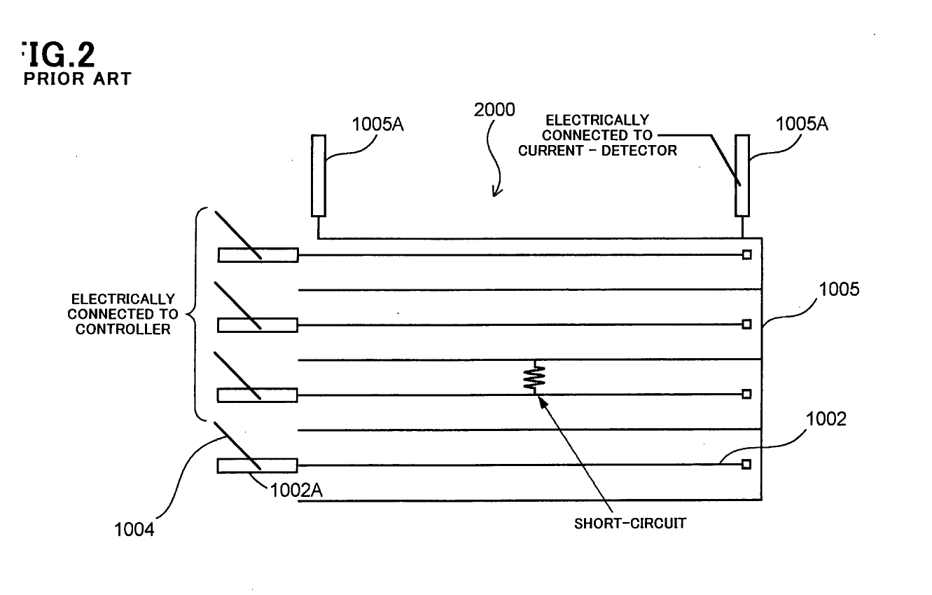

FIG. 3 is a plan view of a TFT substrate including gate wires and COM wires.

FIG. 4 is a block diagram of an apparatus for testing whether wires are defective or not in a substrate, in accordance with the embodiment of the present invention.

FIG. 5 is a block diagram of the controller.

FIG. 6 is a plan view of a TFT substrate including gate wires and COM wires.

FIG. 7 is a graph showing a relation between gate wires and a capacity defined between gate wires and COM wires, found when a probe is directly electrically connected to a capacity-detector.

FIG. 8 is a graph showing a relation between gate wires and a capacity defined between gate wires and COM wires, found when a probe is electrically connected to a capacity-detector through a capacitance.

FIG. 9 is a plan view of a TFT substrate including gate wires and COM wires.

### DESCRIPTION OF THE PREFERRED EMBODIMENTS

Preferred embodiments in accordance with the present invention will be explained hereinbelow with reference to drawings.

Hereinbelow are explained an apparatus for testing whether gate wires fabricated on a TFT substrate are short-circuited with each other and/or are in an open circuit condition, and a method of doing the same.

First, a TFT substrate including gate wires, to be tested is explained hereinbelow.

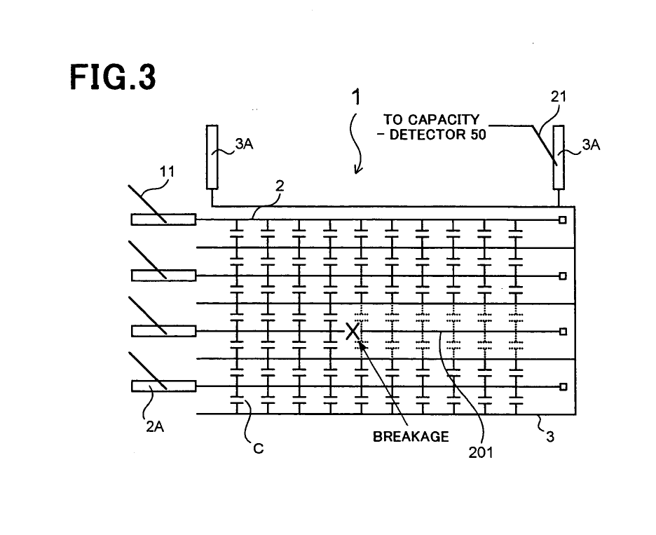

FIG. 3 is a plan view of a TFT substrate including gate wires and COM wires.

As illustrated in FIG. 3, a plurality of gate wires 2 to be tested, and a plurality of COM wires 3 are fabricated on a TFT substrate 1.

The gate wires 2 extend in a line in parallel with one another, and are equally spaced away from one another.

The COM wires 3 extend in a line in parallel with one another, and are equally spaced away from one another.

The gate wires 2 and the COM wires 3 are in parallel with each other, and are alternately arranged on the TFT substrate 1.

The gate wires 2 and the COM wires 3 are formed in a common layer in the TFT substrate 1, that is, are simultaneously formed in a common step.

Each of the gate wires 2 has a gate terminal 2A at an end thereof. As mentioned later, a first probe 11 makes contact with the gate terminal 2A.

The COM wires 3 are collected into one wire at a side opposite to the gate terminals 2A, which is then connected to COM terminals 3A. As mentioned later, a second probe 21 makes contact with the COM terminal 3A.

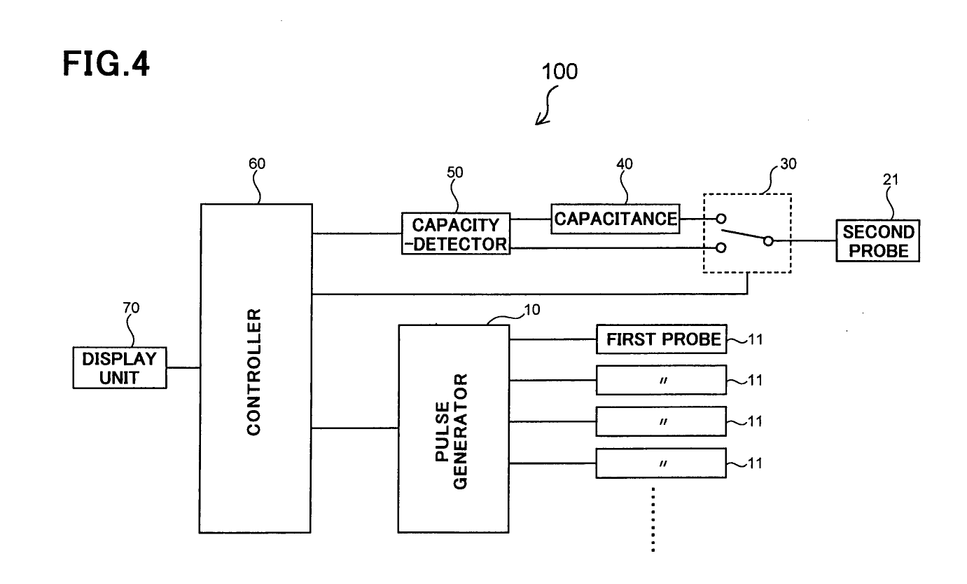

FIG. 4 is a block diagram of an apparatus 100 for testing whether wires are defective or not in a substrate, in accordance with the embodiment of the present invention.

As illustrated in FIG. 4, the apparatus 100 is comprised of a plurality of first probes 11 each of which is caused to make contact with a terminal of a wire to be tested (for instance, the gate terminal 2A of the gate wire 2), a pulse generator 10 generating a voltage pulse to be transmitted to the first probes 11, a second probe 21 caused to make contact with a terminal of a wire which defines a capacity together with a wire to be tested (for instance, the COM terminal 3A of the COM wire 3), a switch 30, a capacitance 40, a capacity-detector 50 detecting a capacity, a controller 60 controlling operation of the pulse generator 10, the switch 30 and the capacity-detector 50, and a display unit 70 displaying images under the control of the controller 60.

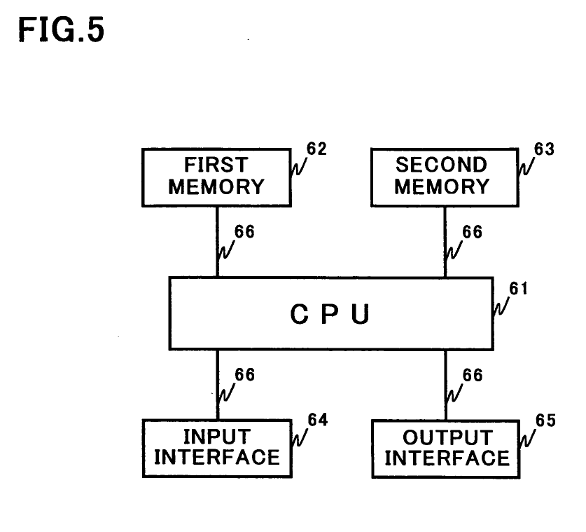

FIG. 5 is a block diagram of the controller 60.

As illustrated in FIG. 5, the controller 60 is comprised of a central processing unit (CPU) 61, a first memory 62, a second memory 63, an input interface 64 through which a command and/or data is input into the central processing unit 61, an output interface 65 through which a result of steps having been executed by the central processing unit 61 is output, and a bus 66 through which the central processing unit 61 is electrically connected with the first memory 62, the second memory 63, the input interface 64, and the output interface 65.

Each of the first and second memories 62 and 63 is comprised of a semiconductor memory such as a read only memory (ROM), a random access memory (RAM) or an IC memory card, or a storage device such as a flexible disc, a hard disc or an optic magnetic disc.

In the embodiment, the first memory 62 comprises a read only memory (ROM), and the second memory 63 comprises a random access memory (RAM).

The first memory 62 stores therein a program for causing a computer to carry out a method of testing whether wires are defective or not. The second memory 63 stores therein various data and parameters, and presents a working area to the central processing unit 61. The central processing unit 61 reads the program out of the first memory 62, and executes the program. Thus, the central processing unit 61 operates in accordance with the program stored in the first memory 62.

The switch 30 operates under the control of the controller 60. Specifically, the switch 30 allows the second probe 21 to be electrically connected to the capacity-detector 50 through the capacitance 40, or allows the second probe 21 to be directly electrically connected to the capacity-detector 50 (that is, without through the capacitance 40).

Hereinbelow is explained an operation of the apparatus 100.

As illustrated in FIG. 3, each of the first probes 11 are caused to make contact with the associated gate terminal 2A, and the second probe 21 is caused to make contact with one of the COM terminals 3A.

Under the control of the controller 60, the switch 30 directly electrically connects the second probe 21 to the capacity-detector 50 without through the capacitance 40.

In such a condition as mentioned above, the pulse generator 10 generates a pulse voltage, and applies the pulse voltage to each of the gate terminals 2A in turn through the associated first probe 11.

For instance, about 1600 gate wires 2 and about 1600 COM wires 3 are formed on the TFT substrate 1, and a number is assigned to each of the gate wires 2 for reasons of convenience. For instance, a gate number 1 to 1600 is assigned to each of the gate wires 2.

The pulse generator 10 earlier applies a pulse voltage in turn to each of the gate wires 2 having a younger gate number.

For instance, a pulse voltage has a rectangular waveform.

When a pulse voltage is applied to each of the gate wires 2, the capacity-detector 50 detects a capacity input thereinto through the second probe 21 and the switch 30. The capacity is a capacity C formed between each of the gate wires 2 and a COM wire 3 disposed adjacent thereto (see FIG. 3). Hereinbelow, such a capacity C is called gate-COM wires capacity.

Herein, a distance between each of the gate wires 2 and a COM wire 3 disposed adjacent thereto is sufficiently shorter than a length of each of the gate wires 2 and each of the COM wires 3.

Hence, it is possible to detect the gate-COM wires capacity C by means of a detector which is capable of detecting a capacity formed in a pixel. For instance, an integration circuit may be used as such as detector. That is, a capacity-detector equipped in a tester which operates in accordance with the conventional pixel capacity detection process may be preferably used as the capacity-detector 50.

It is assumed herein that the gate wire 2 in which breakage occurs is indicated as a gate wire 201, as illustrated in FIG. 3. The gate-COM wires capacity C defined by the gate wire 201 and a COM wire disposed adjacent thereto is smaller than a gate-COM wires capacity C defined by a gate wire 2 (that is, a non-defective gate wire or a gate wire in which no breakage occurs) and a COM wire disposed adjacent thereto.

Accordingly, if a gate-COM wires capacity C detected by the capacity-detector 50 is smaller than a gate-COM wires capacity C defined by a non-defective gate wire 2 and a COM wire disposed adjacent thereto, it is possible to judge that wire breakage occurs in the tested gate wire 2.

However, the apparatus which detects wire breakage by directly electrically connecting the second probe 21 to the capacity-detector 50 is accompanied with a problem that if any one of the gate wires 2 is short-circuited with a COM wire 3 disposed adjacent thereto, since a low pulse voltage is kept applied to the capacity-detector 50, a current keeps running into the capacity-detector 50, resulting in that it is not possible to accurately detect a gate-COM wires capacity C, and hence, it is not possible to accurately detect wire breakage.

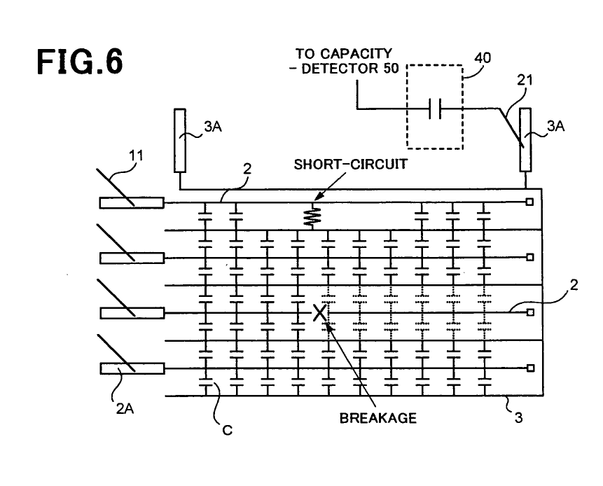

Thus, the controller 60 operates the switch 30 to electrically connect the second probe 21 to the capacity-detector 50 through the capacitance 40, as illustrated in FIG. 6. As a result, it is possible to prevent a current from running into the capacity-detector 50 from a short-circuited point, ensuring it possible to accurately detect wire breakage in the gate wires 2.

As illustrated in FIG. 6, a gate-COM wires capacity C formed when the second probe 21 is electrically connected to the capacity-detector 50 through the capacitor 40, as illustrated in FIG. 6, is smaller than a gate-COM wires capacity C formed when the second probe 21 is directly electrically connected to the capacity-detector 50 (see FIG. 3). However, the obtained gate-COM wires capacity C is sufficient to detect wire breakage and short-circuit. In addition, it is possible to have an improved signal/noise (S/N) ratio by electrically connecting the second probe 21 to the capacity-detector 50 through the capacitance 40.

If the second probe 21 is directly electrically connected to the capacity-detector 50 without through the capacitance 40 (see FIG. 3), it would be quite difficult to detect wire breakage occurring in the vicinity of a proximal end of a gate wire 2, because a gate-COM wires capacity formed between such a gate wire 2 and a COM wire 3 disposed adjacent thereto is smaller than a gate-COM wires capacity formed between a non-defective gate wire 2 and a COM wire 3 disposed adjacent thereto. It would be possible to detect wire breakage occurring in the vicinity of a proximal end of a gate wire 2 by electrically connecting the second probe 21 to the capacity-detector 50 through the capacitance 40, as illustrated in FIG. 6.

Hereinbelow is explained the experimental data.

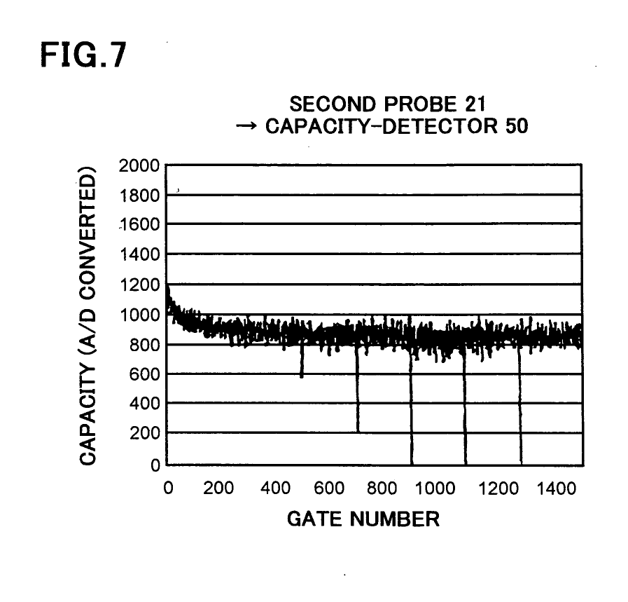

FIG. 7 is a graph showing a relation between the gate wires 2 and a gate-COM wires capacity obtained when the second probe 21 is directly electrically connected to the capacity-detector 50, as illustrated in FIG. 3.

In FIG. 7, an axis of abscissas indicates a number of a gate wire, and an axis of ordinates indicates a gate-COM wires capacity C.

It is assumed herein that among about 1600 gate wires 2, the gate wires 2 are in breakage or in open-circuit at every 200 gate wires, starting from a gate wire 2 having a gate number 100, and that a gate wire having a greater gate number is in breakage or in open-circuit at a location closer to the gate terminal 2A.

There was used a pulse voltage having a rectangular waveform and an intensity of 25 V. The pulse voltage was applied for 255 microseconds.

The higher a pulse voltage is or the longer period of time a pulse voltage is applied, the higher a detection accuracy becomes. Accordingly, as long as the gate wire 2 can withstand a pulse voltage, it is preferable to cause a pulse voltage as high as possible and to apply a pulse voltage to the gate wires 2 in a period of time as long as possible.

As illustrated in FIG. 7, it is understood that among the gate wires 2 which are in an open-circuit condition, a gate wire having breakage occurring at a location closer to the gate terminal 2A has a smaller gate-COM wires capacity, and hence, it is possible to find the breakage more easily.

Since a gate-COM wires capacity C has a correlation with a distance between the gate terminal 2A and a wire breakage location, it is possible to identify where wire breakage occurs in the gate wire 2.

Since wire breakage occurs in the vicinity of a proximal end at the gate wires 2 having gate number 100 and 300 in FIG. 7, a difference between a gate-COM wires capacity C defined between a non-defective gate wire 2 and a COM wire 3 disposed adjacent thereto and a gate-COM wires capacity C defined between a defective gate wire 2 and a COM wire 3 disposed adjacent thereto is too small, resulting in that it is quit difficult to detect the wire breakage (it is possible to detect the wire breakage in dependence on conditions).

It is not possible to detect a gate-COM wires capacity C in accordance with the method having been explained with reference to FIG. 3 in the TFT substrate 1 in which any one of the gate wires 2 is short-circuited with a COM wire 3. Hence, it is possible to find that one of the gate wires 2 is short-circuited with a COM wire 3, but it is not possible to test whether one of the gate wires 2 is in open-circuit condition, in which case, the gate wires 2 are tested in accordance with the test process illustrated in FIG. 6 in which the second probe 21 is electrically connected to the capacity-detector 50 through the capacitance 40.

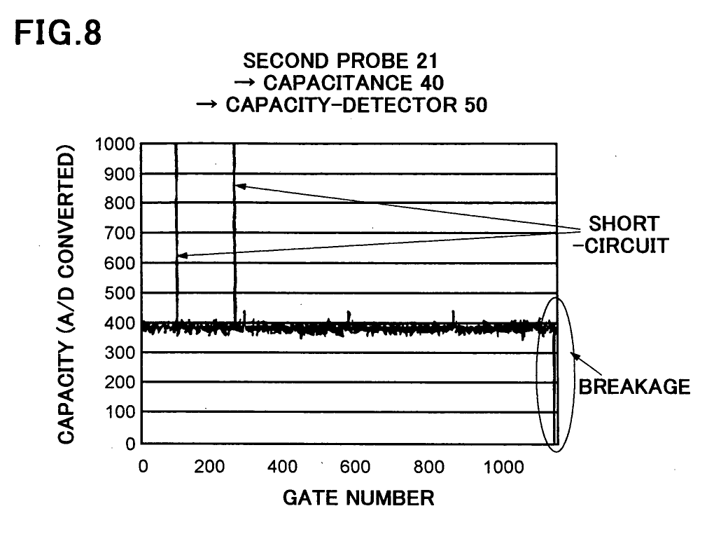

FIG. 8 is a graph showing a relation between the gate wires 2 and a gate-COM wires capacity obtained when the second probe 21 is electrically connected to the capacity-detector 50 through the capacitance 40, as illustrated in FIG. 6.

In FIG. 8, an axis of abscissas indicates a number of a gate wire, and an axis of ordinates indicates a gate-COM wires capacity C.

As illustrated in FIG. 8, it is possible to detect wire breakage or open-circuit condition and short-circuit in the TFT substrate 1 by electrically connecting the second probe 21 to the capacity-detector 50 through the capacitance 40. Even at a proximal end of a gate wire 2, a gate-COM wires capacity C formed between a defective gate wire 2 and a COM wire disposed adjacent thereto is smaller than a gate-COM wires capacity C formed between a non-defective gate wire 2 and a COM wire disposed adjacent thereto, ensuring it possible to detect wire breakage or open-circuit condition of a gate wire 2.

The capacity-detector 50 outputs data of the detection results to the controller 60. The controller 60 makes such graphs as illustrated in FIGS. 7 and 8, based on the data input from the capacity-detector 50, and displays the graphs in the display unit 70.

In accordance with the above-mentioned embodiment, a gate-COM wires capacity C is detected by the capacity-detector 50 electrically connected to the COM wires 3, while a voltage is being applied to the gate wires 2. Thus, it is possible to find wire breakage in the gate wires 2 in the TFT substrate 1 even before pixels and transistors are fabricated, through the use of a simple tester, that is, the apparatus 100.

Thus, line defect can be soon found, ensuring enhancement in a yield of final products. This is because even defects which cannot be removed after completion of a TFT substrate can be removed by repairing or reconstruction.

Furthermore, it is possible to find both wire breakage and short-circuit in the gate wires 2 in the TFT substrate 1 by electrically connecting the second probe 21 to the capacity-detector 50 through the capacitance 40, through the use of a simple tester, that is, the apparatus 100.

In the above-mentioned embodiment, the gate wires 2 are to be tested, and a gate-COM wires capacity C is formed between the gate wires 2 and the COM wire 3. It is possible to detect defects in a combination of wires extending in parallel with each other, other than a combination of the gate wires 2 and the COM wires 3, similarly to the above-mentioned embodiment.

In the above-mentioned embodiment, the gate wires 2 to be tested and the COM wires 3 which cooperate with the gate wires 2 to define a gate-COM wires capacity C therebetween are formed in a common layer in the TFT substrate 1. If the gate wires 2 and the COM wires 3 are in parallel with each other, it would be possible to detect defects existing in them, even though they are formed in different layers in the TFT substrate 1.

In the above-mentioned embodiment, the gate wires 2 to be tested and the COM wires 3 which cooperate with the gate wires 2 to define a gate-COM wires capacity C therebetween are in parallel with each other. Even though the gate wires 2 and the COM wires 3 are not in parallel with each other, it is theoretically possible to detect defects in the gate wires 2, similarly to the above-mentioned embodiment.

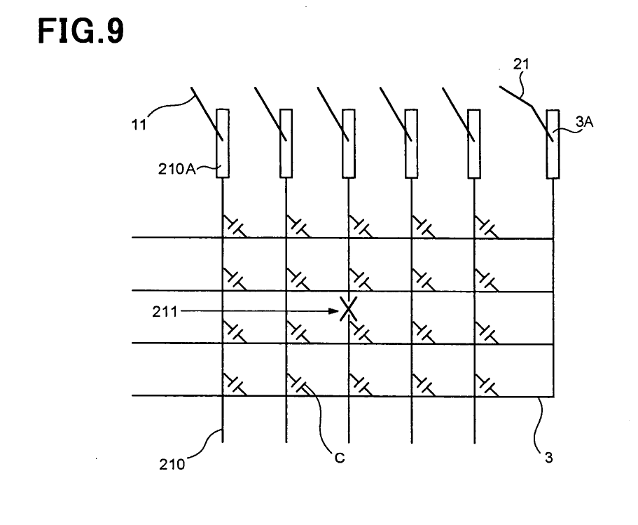

Hereinbelow is explained the reason with reference to FIG. 9.

FIG. 9 is a plan view of a TFT substrate including gate wires and COM wires.

As illustrated in FIG. 9, a plurality of drain wires 210 and a plurality of COM wires 3 extend perpendicularly to each other. Each of the drain wires 210 is designed to have a drain terminal 210A at an end thereof. The first probe 11 is caused to make contact with each of the drain terminals 210A. The COM wires 3 are collected at an end thereof to a single wire having a COM terminal 3A at an end thereof. The second probe 21 is caused to make contact with the COM terminal 3A.

A capacity C is formed at each of intersections of the drain wires 201 and the COM wires 3, as illustrated in FIG. 9. Accordingly, it is possible to detect defects 211 existing in one or more of the drain wires 201 in a manner similar to the above-mentioned embodiment.

The above-mentioned apparatus 100 is designed to include the switch 30 for electrically connecting the second probe 21 either directly to the capacity-detector 50 or to the capacity-detector 50 through the capacitance 40. It is not always for the apparatus 100 to include the switch 30. The apparatus 100 may be designed not to include the switch 30, in which case, the second probe 21 is kept electrically connected to the capacity-detector 50 through the capacitance 40.

Furthermore, the above-mentioned apparatus 100 is designed to include the capacitance 40. It is not always for the apparatus 100 to include the capacitance 40. The apparatus 100 may be designed not to include the capacitance 40.

In the above-mentioned apparatus 100, a pulse voltage is input into the gate wires 2, and the COM wires 3 are electrically connected to the capacity-detector 50. In contrast, a pulse voltage may be input into the COM wires 3, and the gate wires 2 may be electrically connected to the capacity-detector 50. In other words, the apparatus 100 for testing whether first wires (for instance, the gate wires 2) are defective or not in a substrate including a plurality of the first wires to be tested, and a plurality of second wires (for instance, the COM wires 3) each defining a capacity with each of the first wires may be designed to include a voltage-applier (for instance, the pulse generator 10) for applying a voltage to the second wires, and a capacity-detector (for instance, the capacity-detector 50) for detecting a capacity defined between the first and second wires.

It is preferable in the above-mentioned apparatus 100 that the capacity-detector (for instance, the capacity-detector 50) is electrically connected to the first wires (for instance, the gate wires 2), and the apparatus 100 further includes a capacitance (for instance, the capacitance 40) electrically connected between the first wires and the capacity-detector.

It is preferable for the above-mentioned apparatus 100 to further include a capacitance (for instance, the capacitance 40) to be electrically connected between the first wires (for instance, the gate wires 2) and the capacity-detector (for instance, the capacity-detector 50), and a switch (for instance, the switch 30) defining one of a first condition in which the first wires are electrically connected to the capacity-detector through the capacitance, and a second condition in which the first wires are electrically connected to the capacity-detector without through the capacitance.

While the present invention has been described in connection with certain preferred embodiments, it is to be understood that the subject matter encompassed by way of the present invention is not to be limited to those specific embodiments. On the contrary, it is intended for the subject matter of the invention to include all alternatives, modifications and equivalents as can be included within the spirit and scope of the following claims.

The entire disclosure of Japanese Patent Application No. 2006-1439 filed on Jan. 6, 2006 including specification, claims, drawings and summary is incorporated herein by reference in its entirety.

What is claimed is:

1. In a substrate including a plurality of first wires to be tested, and a plurality of second wires each defining a capacity with each of said first wires, a method of testing whether said first wires are defective or not, comprising:
(a) applying a voltage to said first wires; and
(b) detecting a capacity defined between said first and second wires while said step (a) is being carried out.

2. The method as set forth in claim 1, wherein said step (b) is carried out by means of a capacity-detector electrically connected to said second wires.

3. The method as set forth in claim 2, wherein said step (b) is carried out with a capacitance being electrically connected between said second wires and said capacity-detector.

4. The method as set forth in claim 1, wherein said first and second wires extend almost in parallel with each other.

5. The method as set forth in claim 1, wherein said first and second wires are formed in a common layer.

6. The method as set forth in claim 1, wherein said second wires are collected into one terminal.

7. In a substrate including a plurality of first wires to be tested, and a plurality of second wires each defining a capacity with each of said first wires, a method of testing whether said first wires are defective or not, comprising:
(a) applying a voltage to said second wires; and
(b) detecting a capacity defined between said first and second wires while said step (a) is being carried out.

8. The method as set forth in claim 7, wherein said step (b) is carried out by means of a capacity-detector electrically connected to said first wires.

9. The method as set forth in claim 8, wherein said step (b) is carried out with a capacitance being electrically connected between said first wires and said capacity-detector.

10. The method as set forth in claim 7, wherein said first and second wires extend almost in parallel with each other.

11. The method as set forth in claim 7, wherein said first and second wires are formed in a common layer.

12. The method as set forth in claim 7, wherein said second wires are collected into one terminal.

13. An apparatus for testing whether first wires are defective or not in a substrate including a plurality of said first wires to be tested, and a plurality of second wires each defining a capacity with each of said first wires, comprising:
(a) a voltage-applier for applying a voltage to said first wires; and
(b) a capacity-detector for detecting a capacity defined between said first and second wires.

14. The apparatus as set forth in claim 13, wherein said capacity-detector is electrically connected to said second wires.

15. The apparatus as set forth in claim 14, further comprising a capacitance electrically connected between said second wires and said capacity-detector.

16. The apparatus as set forth in claim 14, further comprising:
a capacitance to be electrically connected between said second wires and said capacity-detector; and
a switch defining one of a first condition in which said second wires are electrically connected to said capacity-detector through said capacitance and a second condition in which said second wires are electrically connected to said capacity-detector without through said capacitance.

17. The apparatus as set forth in claim 13, wherein said first and second wires extend almost in parallel with each other.

18. The apparatus as set forth in claim 13, wherein said first and second wires are formed in a common layer.

19. The apparatus as set forth in claim 13, wherein said second wires are collected into one terminal.

20. An apparatus for testing whether first wires are defective or not in a substrate including a plurality of said first wires to be tested, and a plurality of second wires each defining a capacity with each of said first wires, comprising:
(a) a voltage-applier for applying a voltage to said second wires; and
(b) a capacity-detector for detecting a capacity defined between said first and second wires.

21. The apparatus as set forth in claim 20, wherein said capacity-detector is electrically connected to said first wires.

22. The apparatus as set forth in claim 21, further comprising a capacitance electrically connected between said first wires and said capacity-detector.

23. The apparatus as set forth in claim 21, further comprising:
a capacitance to be electrically connected between said first wires and said capacity-detector; and
a switch defining one of a first condition in which said first wires are electrically connected to said capacity-detector through said capacitance and a second condition in which said first wires are electrically connected to said capacity-detector without through said capacitance.

24. The apparatus as set forth in claim 20, wherein said first and second wires extend almost in parallel with each other.

25. The apparatus as set forth in claim 20, wherein said first and second wires are formed in a common layer.

26. The apparatus as set forth in claim 20, wherein said second wires are collected into one terminal.

27. A program for causing a computer to carry out a method of, in a substrate including a plurality of first wires to be tested, and a plurality of second wires each defining a capacity with each of said first wires, testing whether said first wires are defective or not, steps executed by said computer in accordance with said program including:
(a) applying a voltage to one of said first wires and said second wires; and
(b) detecting a capacity defined between said first and second wires while said step (a) is being carried out.
